(19) United States
(12) Patent Application Publication
(10) Pub. No.: US 2016/0198593 A1
(43) Pub. Date: Jul. 7, 2016

(54) MIXED/MULTI-MODE COOLING USING AIR HANDLING UNITS (AHU) PROVIDING DIRECTED CONTROLLED COOLING TO A MODULAR DATA CENTER

(71) Applicant: DELL PRODUCTS, L.P., Round Rock, TX (US)

(72) Inventors: TY SCHMITT, ROUND ROCK, TX (US); MARK BAILEY, ROUND ROCK, TX (US); TREY WIEDERHOLD, CEDAR PARK, TX (US); TYLER DUNCAN, AUSTIN, TX (US)

(73) Assignee: DELL PRODUCTS, L.P., ROUND ROCK, TX (US)

(21) Appl. No.: 14/590,829

(22) Filed: Jan. 6, 2015

(51) Int. Cl. H05K 7/20

(52) U.S. Cl. CPC H05K 7/20745; H05K 7/20836

(57) ABSTRACT

A cooling system that provides cooling air for an operating space of a large scale information handling system (IHS) by using an air handling unit (AHU) configured to direct cooling air through the IHS. A controller is in communication with an ambient condition interface and the AHU to cause the cooling system to (i) detect the outside ambient condition; (ii) determine whether the outside ambient condition has first condition values that support use of normal cooling mode or second condition values that requires/triggers a hybrid cooling mode; and (iii) in response to determining that the outside ambient condition has the second condition values, perform a hybrid mode mixing of the outside air with recirculated air to moderate the outside air to more efficiently cool the IHS. The cooling system is thus responsive to current/detected conditions and provides an operational mode that yields highest cooling efficiency for the existing ambient condition/s.

### BACKGROUND

1. Technical Field

The present disclosure relates in general to cooling information handling resources of a modular data center, and more particularly to using air handling units (AHUs) to provide directed and controlled cooling to a large scale information handling system (IHS).

2. Description of the Related Art

As the value and use of information continue to increase, individuals and businesses seek additional ways to process and store information. One option available to users is information handling systems (IHSes). An IHS generally processes, compiles, stores, and/or communicates information or data for business, personal, or other purposes, thereby allowing users to take advantage of the value of the information. Because technology and information handling needs and requirements vary between different users or applications, IHSes may also vary regarding what information is handled, how the information is handled, how much information is processed, stored, or communicated, and how quickly and efficiently the information may be processed, stored, or communicated. The variations in IHSes allow for IHSes to be general or configured for a specific user or specific use such as financial transaction processing, airline reservations, enterprise data storage, or global communications. In addition, IHSes may include a variety of hardware and software components that may be configured to process, store, and communicate information and may include one or more computer systems, data storage systems, and networking systems.

As the capabilities of information handling systems have improved, the power requirements of IHSes and their component information handling resources have increased. Accordingly, the amount of heat produced by such information handling resources has increased. Because the electrical properties of information handling resources may be adversely affected by the presence of heat (e.g., heat may damage sensitive information handling resources and/or some information handling resources may not operate correctly outside of a particular range of temperatures), information handling systems often include cooling systems configured to cool such information handling resources.

The construction and configuration of cooling systems may be of particular difficulty in data centers. A data center will typically include multiple IHSes (e.g., servers), which may be arranged in racks. Modular data centers further arrange these racks in modular building blocks. Each IHS and its component information handling resources may generate heat, which can adversely affect the various IHSes and their component information handling resources if the generated heat is not efficiently removed or reduced. To cool information handling systems in data centers, information handling systems are often cooled via the impingement of air driven by one or more air movers. To effectively control the temperature of information handling resources, especially in installations in which a modular data center is outdoor-exposed (e.g., those placed on building roofs or elsewhere), the modular data center must provide support for extreme temperatures, weather, and airflow ranges. However, relying solely upon mechanical cooling can be costly and lead to other secondary problems with air quality and others that can negatively affect the IHSes.

### BRIEF SUMMARY

In accordance with the teachings of the present disclosure, the amount of resources necessary for cooling a data center comprising information handling systems has been substantially reduced by implementation of mixed-mode cooling, which includes selective use of mechanical cooling and/or recirculation of exhaust air along with a regulated flow of outside air. Mixed-mode cooling of the data center is automatically triggered to occur whenever internal or external conditions that require mixed-mode cooling are present, such as when the outside air temperature and/or the outside air humidity are not within their respective acceptable range.

In accordance with embodiments of the present disclosure, a cooling system provides cooling air for an operating space of a large scale information handling system (IHS). In one embodiment, the cooling system includes an air handling unit (AHU) configured to direct cooling air through an information technology (IT) module within the IHS. The cooling system includes an ambient condition interface in communication with at least one outside ambient condition sensor that detects an ambient condition outside of the IHS. The cooling system includes a controller in communication with the ambient condition interface and the AHU to cause the cooling system to: (i) detect the outside ambient condition; (ii) determine whether the outside ambient condition is within a first range of condition values that requires a normal cooling mode or within a second range of condition values that requires a hybrid cooling mode; and (iii) in response to determining that the outside ambient condition falls within the first range of condition values, configure the AHU to circulate cooling air through the IHS by: (a) intaking outside air; and (b) circulating the outside air through the IHS operating space. The controller further causes or configures the cooling system to: (iv) in response to determining that the outside ambient condition falls within the second range of condition values, configure the AHU to circulate cooling air through the IHS by: (a) intaking outside air; (b) performing a hybrid mode mixing of the outside air with recirculated air to moderate the outside air and bring a condition value of the moderated outside air into the first range of condition values; and (c) circulating the moderated outside air through the IHS operating space.

According to illustrative embodiments of the present disclosure, a method is provided for cooling IT modules within a large scale IHS having an AHU. In one embodiment, the method includes detecting an outside ambient condition. The method includes determining whether the outside ambient condition is within a first range of condition values that requires normal cooling mode or within a second range of condition values that requires a hybrid cooling mode. The method further includes, in response to determining that the outside ambient condition falls within the first range of condition values, configuring the AHU to circulate cooling air through the IHS by: intaking outside air; and circulating the outside air through the IHS operating space. The method includes, in response to determining that the outside ambient condition falls within the second range of condition values, configuring the AHU to circulate cooling air through the IHS by: intaking outside air; performing a hybrid mode mixing of the outside air with recirculated air to moderate the outside air and bring a condition value of the moderated outside air into the first range of condition values; and circulating the moderated outside air through the IHS operating space.

The above presents a general summary of several aspects of the disclosure in order to provide a basic understanding of at least some aspects of the disclosure. The above summary contains simplifications, generalizations and omissions of detail and is not intended as a comprehensive description of the claimed subject matter but, rather, is intended to provide a brief overview of some of the functionality associated therewith. The summary is not intended to delineate the scope of the claims, and the summary merely presents some concepts of the disclosure in a general form as a prelude to the more detailed description that follows. Other systems, methods, functionality, features and advantages of the claimed subject matter will be or will become apparent to one with skill in the art upon examination of the following figures and detailed written description.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1A illustrates a diagrammatic side view of a mixed and multi-mode cooling system that configures an air handling unit (AHU) to cool an information technology (IT) module of a data center via standard mode cooling, according to one or more embodiments;

FIG. 1B illustrates a diagrammatic top view of a mixed and multi-mode cooling system of FIG. 1A that configures an AHU to cool an IT module of a data center via standard mode cooling, according to one or more embodiments;

FIG. 2A illustrates a diagrammatic side view of the mixed and multi-mode cooling system of FIG. 1A that configures the AHU to cool the IT module of the data center via mixed mode cooling, according to one or more embodiments;

FIG. 2B illustrates a diagrammatic top view of the mixed and multi-mode cooling system of FIG. 2A that configures the AHU to cool the IT module of the data center via mixed mode cooling, according to one or more embodiments;

FIG. 3A illustrates a diagrammatic side view of the mixed and multi-mode cooling system of FIG. 1A that configures the AHU to cool the IT module of the data center using mechanical trimming, according to one or more embodiments;

FIG. 3B illustrates a diagrammatic top view of the mixed and multi-mode cooling system of FIG. 3A that configures the AHU to cool the IT module of the data center using mechanical trimming, according to one or more embodiments;

FIG. 4A illustrates a diagrammatic side view of the mixed and multi-mode cooling system of FIG. 1A that configures the AHU to cool the IT module of the data center via a closed mode cooling, according to one or more embodiments;

FIG. 4B illustrates a diagrammatic top view of the mixed and multi-mode cooling system of FIG. 4A that configures the AHU to cool the IT module of the data center via a closed mode cooling, according to one or more embodiments;

FIG. 5 illustrates a psychometric chart of an exemplary mapping of outside temperatures values and outside humidity values that trigger cooling via normal mode that uses outside air, a mixed mode, and mechanical trim mode for all ranges of temperature and humidity with mechanical cooling (or closed) mode used for contamination, according to one or more embodiments;

FIG. 6 illustrates an exemplary power and computing environment of the mixed and multi-mode cooling system of FIG. 1 that configures the AHU to cool the IT module of the data center, according to one or more embodiments;

FIG. 7 illustrates a flow diagram of a method for cooling IT modules with an appropriate one or four modes within a large scale information handling system (IHS) having an AHU, according to one or more embodiments;

FIG. 8 illustrates a flow diagram of a method for cooling IT modules within a large scale IHS having an AHU, according to one or more embodiments;

FIG. 9 illustrates a flow diagram of an alternative method for cooling IT modules within a large scale IHS having an AHU, according to one or more embodiments; and

FIGS. 10A-10B illustrate a flow diagram of an exemplary method of cooling a data center with a mixed mode cooling that utilizes outside air for greater economy in an expanded range of temperatures and humidity, according to one or more embodiments.

### DETAILED DESCRIPTION

The present disclosure provides a cooling system that includes an air handling unit (AHU) that circulates cooling air through an information technology (IT) module containing rack-based information handling systems. The cooling system circulates the cooling air in one of a plurality of cooling modes based on one or more detected conditions in and around the data center. The AHU utilizes a normal mode cooling, which does not require use of mechanically cooled or recirculated air within the data center, when outside temperature and/or humidity are within an acceptable range. For increased economy and other reasons, the AHU can be configured for a hybrid mode that utilizes a mixture of outside air and one of mechanically cooled or recirculated air when the outside temperature and/or outside humidity are not within the acceptable range. For example, a first hybrid mode can address when the outside temperature value is below the acceptable temperature range by configuring the AHU to perform a mixed mode cooling of the IT module. Mixed mode includes (i) partially opening a recirculation damper between a hot air return plenum and an air intake chamber to recirculate a portion of return air into the air intake chamber, (ii) opening an outside air intake damper at an outside air intake to an air intake chamber, and (iii) opening an exhaust damper between the hot air return plenum and an exhaust portal, such as a chimney. A second hybrid mode can also address when the outside temperature and/or humidity is above acceptable range by configuring the AHU to perform mechanical trimming of the outside air. Direct expansion cooling of the outside air creates moderated outside air that is within the acceptable range. Collectively, the first and second hybrid modes are simply referenced herein as hybrid mode. It is appreciated that additional hybrid modes can be added in alternate embodiments, falling within the extended scope of the disclosure.

In the following detailed description of exemplary embodiments of the disclosure, specific exemplary embodiments in which the disclosure may be practiced are described in sufficient detail to enable those skilled in the art to practice the disclosed embodiments. For example, specific details such as specific method orders, structures, elements, and connections have been presented herein. However, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure. The following detailed description is, therefore, not to be taken in a limiting sense, and the scope of the present disclosure is defined by the appended claims and equivalents thereof.

References within the specification to “one embodiment,” “an embodiment,” “embodiments”, or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

It is understood that the use of specific component, device and/or parameter names and/or corresponding acronyms thereof, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

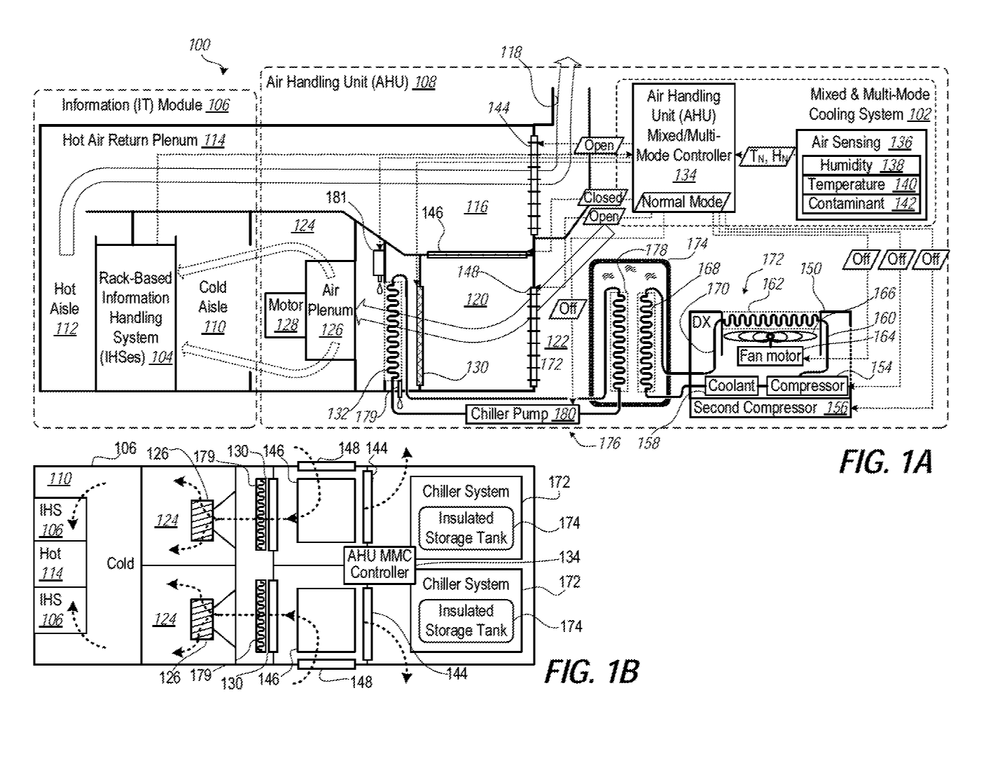

FIGS. 1A-1B illustrate a block diagram representation of an example data center 100 having a mixed and multi-mode cooling (MMC) system 102 that can reduce energy costs by expanding use of outside air for cooling. The term mixed mode refers to using recirculated air to warm outside air that is otherwise too cold (or too humid). Multi-mode refers to performing mechanical cooling while using outside cooling air, via a process referred to herein as mechanical trimming. The expanded use of outside air includes partial use of outside air even when the outside temperature and the outside humidity are not within an acceptable range for information handling systems (IHSes) 104 within an information technology (IT) module 106 of the data center 100. In one embodiment, the MMC system 102 directly controls an air handling unit (AHU) 108 that provides cooling to at least one IT module within modular data center 100. In at least one embodiment, the data center 100 is and/or is configured as an Expandable Modular Information Technology (IT) Building Infrastructure (EMITBI). Further, because of the relatively large scale of data center 100 and the use of modular building blocks that house the IT gear within the data center 100, the combination of IT modules 106 that are cooled by the AHUs 108 are collectively referred to herein as a modularly-constructed, large-scale information handling system (LIHS) or simply an 104.

Within the general context of IHSes, an information handling system (IHS) 104 may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network storage device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communication between the various hardware components. It is appreciated that the IHS described within the present disclosure is a LIHS, with servers acting as the individual processing units.

Data center 100 of FIG. 1A (with top view of some components also illustrated by FIG. 1B) includes an IT module 106 having a row of rack-mounted IHSes 104 that separate a cold aisle 110 from a hot aisle 112, which is in fluid communication with a hot air return plenum 114. The AHU 108 includes a return chamber 116 that is in fluid communication with the hot air return plenum 114. The AHU 108 includes an exhaust portal, such as, but not limited to, an exhaust chimney 118, which is in in fluid communication with the return chamber 116. The AHU 108 includes an intake chamber 120 that is fluid communication with the return chamber 116 and an outside environment 122. In one embodiment, the exhaust chimney 118 mitigates warmed air from being drawn into the intake chamber 120. However, an exhaust portal can be flush mounted, relying on spacing to prevent inadvertent recirculation. It is appreciated that the outside environment encompasses some or all of the exterior of the AHU 108 and data center 100, and the specific location illustrated within FIG. 1A only references one location adjacent/relative to the intake chamber 120 for simplicity in describing the intake process of external air. The AHU 108 includes an air mover to move air through the IT module 106. Specifically, the AHU 108 includes an outlet chamber 124 that is uniformly pressurized by an air plenum blower 126 driven by a motor 128. The air plenum blower 126 pulls air in axially and sprays it out radially within an enclosed space to pressurize evenly. The air plenum blower 126 draws air from the intake chamber 120 through a contaminant filter 130 and a chiller coil 132. The pressurized air in the outlet chamber 124 exits the AHU 108 and enters the cold aisle 110 of the IT module 106.

The AHU 108 can be configured for a mode of cooling that is appropriate for the outside ambient conditions. In one or more embodiments, the AHU 108 can be configured by the MMC system 102 for one of (1) a normal mode, (2) a mixed mode, (3) a mechanical trim mode, and (4) a closed mode. FIG. 1A illustrates the AHU 108 having an AHU MMC controller 134 that is responsive to air sensing components 136. Air sensing components 136 can include, but are not limited to, a humidity sensor 138, a temperature sensor 140, and a gas/liquid/solid contaminant sensor 142. When the air sensing components 136 indicate that the ambient temperature of the exterior air is within an acceptable (or normal) range (T_{N}) and that the humidity of the exterior air is also within an acceptable range (H_{N}), the AHU MMC controller 134 configures the AHU 108 for normal mode cooling, which involves using only the outside air for cooling of the IHSes. An exhaust damper 144 is opened between the return chamber 116 and the exhaust chimney 118 to allow the exhaust air to exit the AHU 108. Simultaneously or concurrently, a recirculation damper 146 is closed between the return chamber 116 and the intake chamber 120 to prevent recirculation of the exhaust air. An outside air intake damper 148 is opened, allowing outside air from the outside environment 122 to enter the AHU 108. In normal mode, a direct expansion (DX) cooling unit 150 that supports the AHU 108 remains off.

FIGS. 1A, 1B, 2A, 2B, 3A, 3B, 4A and 4B illustrate the DX cooling unit 150 having a first compressor 154 and a second compressor 156 for stepped performance. The compressors 154, 156 compress and move compressed (liquid) coolant on a high side from a coolant tank 158 through a discharge line 160 and through a condenser coil 162. A condenser fan motor 164 drives a condenser fan 166 to move condensing air through the condenser coil 162. The condensing air convectively removes heat (generated during the compression) from the coolant. An expansion device (not shown) downstream of the condenser coil 162 causes expansion cooling by creating a pressure loss between the high and low sides of the DX cooling unit 150. An evaporator coil 168 transfers heat from its ambient environment to the coolant that is then pulled from a suction line 170 back to the coolant tank 158. In one embodiment, the DX cooling unit 150 is part of a chiller system 172 in order to avoid short cycling of the compressor 154. The DX cooling unit 150 chills water in an insulated storage tank 174 that is cooled by the evaporator coil 168. The chiller system 172 then includes a heat exchanger 176 that includes the chiller coil 132 and a heat sink coil 178 in the insulated storage tank 174. The AHU MMC controller 134 activates a chiller pump 180 to move coolant through the chiller coil 132 and a heat sink coil 178. The compressor 154 can operate for a period of time that is efficient with the insulated storage tank 174 supplying an amount of cooling as needed by pumping a determined flow rate.

The DX cooling unit 150 can serve as a dehumidifier 179 that removes moisture as condensate at the chiller coil 132. Thereby, outside humidity value that is above the acceptable range, or would become too high during mechanical trim mode, can be removed. In addition, in one embodiment, the MMC cooling system 102 can include a humidifier 181 that increases the level of humidity in the moderated outside air by adding moisture.

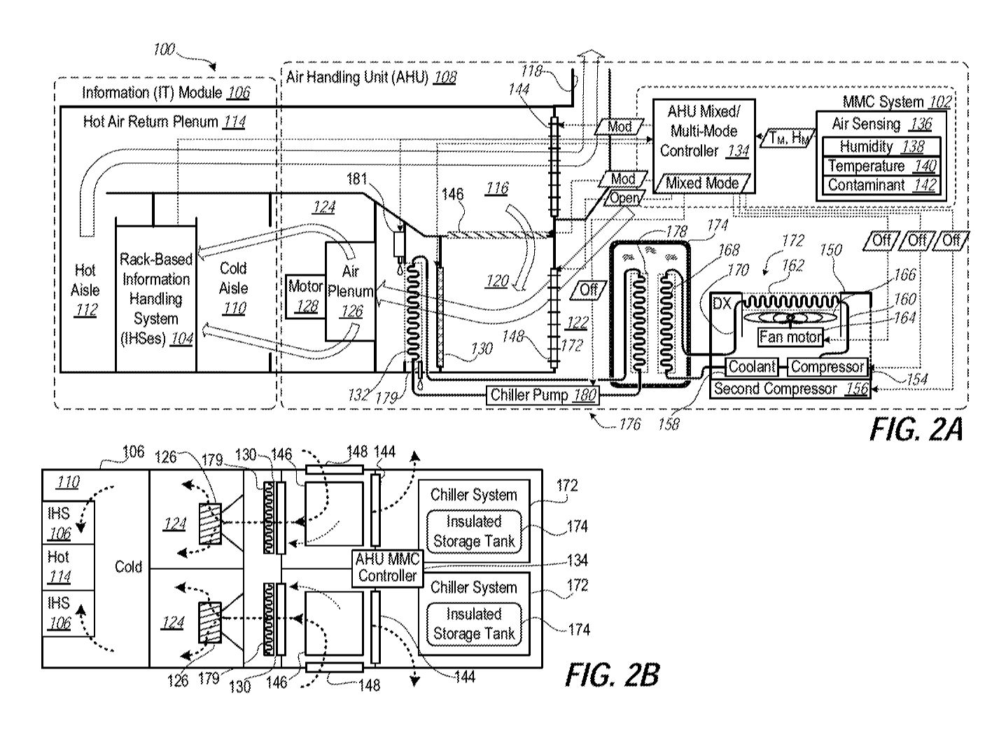

FIGS. 2A-2B illustrate the AHU MMC controller 134 configuring the AHU 108 for mixed mode cooling by (i) opening the exhaust damper 144, (ii) modulating the recirculation damper 146 as necessary to warm the outside air, and (iii) opening the outside air intake damper 148. In mixed mode, the DX cooling unit 150 is off. For mixed mode, the outside environment 122 is colder than acceptable for normal mode (T_{M}). Recirculating a portion of the hot exhaust air from the IT module 106 warms the outside air to an acceptable temperature. Warming the air in mixed mode reduces the dew point of the resultant cooling air within the AHU 108. Generally, this reduction in relative humidity of the outside humidity value (H_{M}) results in a modified humidity value that remains within an acceptable range.

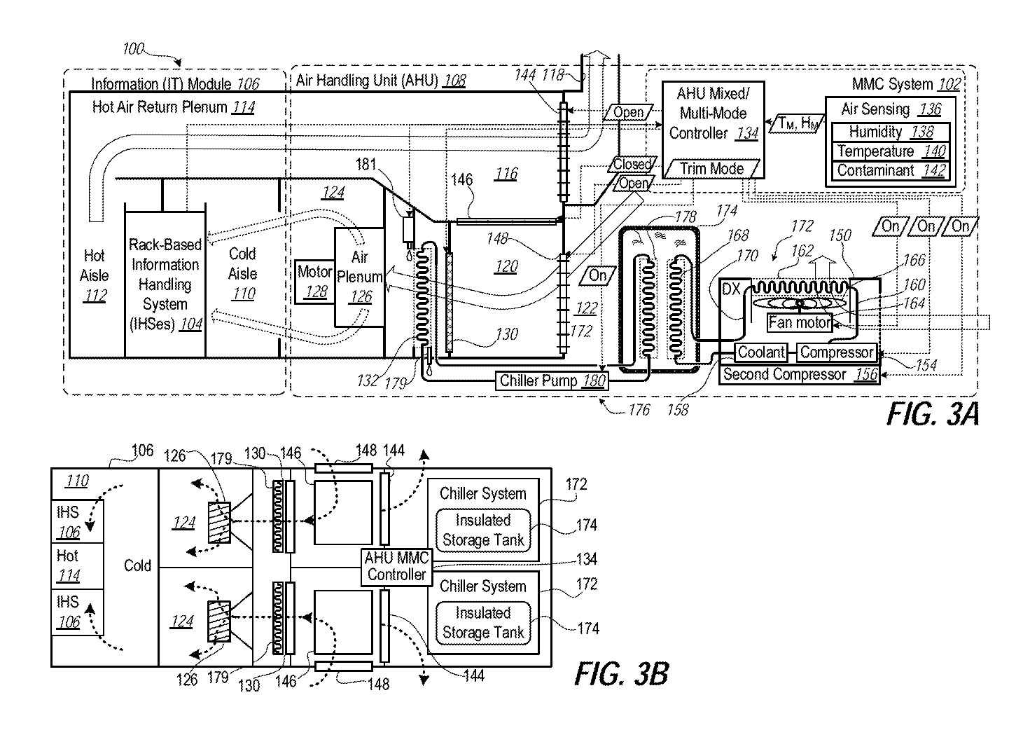

FIGS. 3A-3B illustrate the AHU MMC controller 134 configuring the AHU 108 for mechanical trim cooling mode by (i) opening the exhaust damper 144, (ii) closing the recirculation damper 146, and (iii) opening the outside air intake damper 148. For mechanical trim mode, the AHU 108 realizes power efficiencies of cooling with outside air with some additional cooling provided by the DX cooling unit 150 that is operating at a stepped down mode. For clarity, FIG. 3A illustrates no recirculation for mechanical trim mode. The mechanical cooling sufficiently moderates cooling air that is 100% outside air. In one or more embodiments, the amount of recirculation within the AHU 108 can be modulated for purposes such as making the cooling air drier. The AHU MMC controller 134 triggers the mechanical trim mode in response to the outside temperature value (T_{T}) and the outside humidity value (H_{T}) each being within a mechanical trim range. The outside air can be cooled to the acceptable temperature range by the DX cooling unit 150, while maintaining or bringing the humidity within the acceptable humidity range.

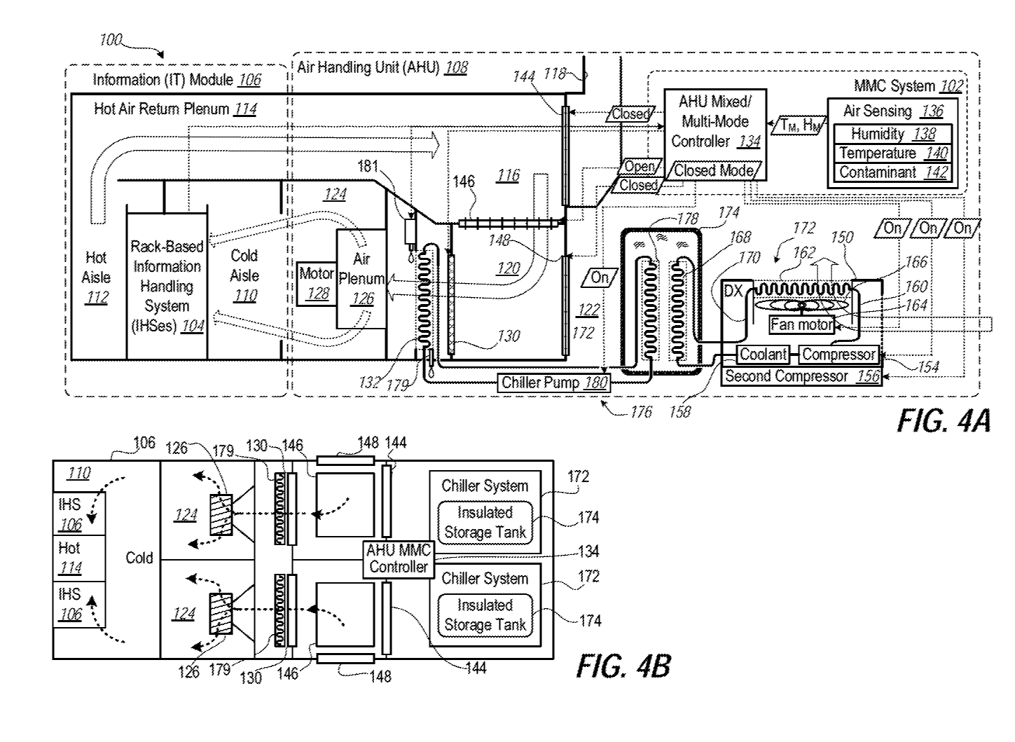

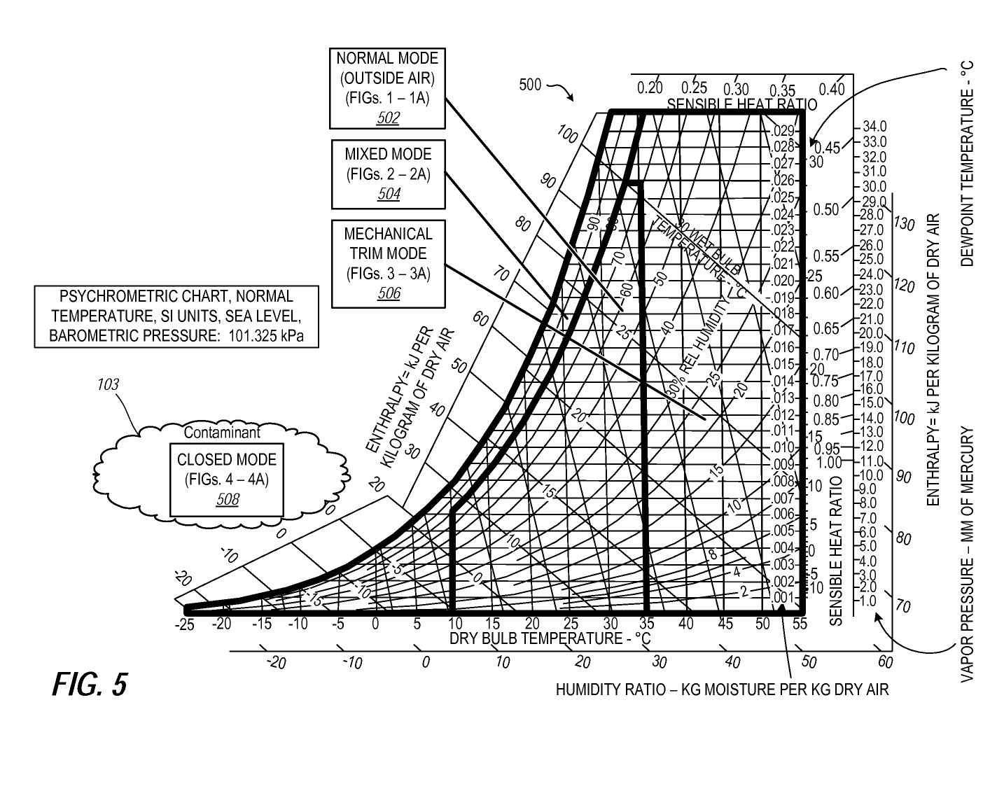

FIGS. 4A-4B illustrate the AHU MMC controller 134 configuring the AHU 108 for closed mode cooling by (i) closing the exhaust damper 144, (ii) opening the recirculation damper 146, and (iii) closing the outside air intake damper 148. Closed mode cooling is used when the outside ambient conditions (T_{C}, H_{C}) are not conducive to use outside air for cooling. For example, the DX cooling unit 150 may not have separate stages/compressors that allow for a reduced amount of mechanical cooling suitable for mechanical trim mode. For another example, the outside temperature and/or humidity can be too high for mechanical trim to remove enough heat and/or humidity to reach an acceptable range. When the MMC system 102 is operating in the closed mode, the DX cooling unit 150 provides all of the cooling necessary to maintain the IT module 106 within an acceptable temperature and humidity range.

TABLE 1 summarizes the configurations of the AHU 108 for the exemplary four (4) modes of normal mode (FIGS. 1A-1B), mixed mode (FIGS. 2A-2B), mechanical trimmed mode (FIGS. 3A-3B), and closed mode (FIGS. 4A-4B):

TABLE 1

| | Intake | Recirculation | Exhaust | |
|---|---|---|---|---|
| | Damper | Damper | Damper | Chiller |
| Mode 1: Normal | Open | Closed | Open | Off |
| Mode 2: Mixed | Open | Modulated 0-100% | Conversely | Off |
| | | | Mod 100-0% | |
| Mode 3: Trim | Open | Modulated 0-100% | Conversely | On |
| | | | Mod 100-0% | |
| Mode 4: Closed | Closed | Open | Closed | On |

FIG. 5 illustrates an example psychometric chart 500 of an illustrative mapping of outside temperatures values and outside humidity values for the various cooling modes, from among a normal mode 502 that uses only outside air, a mixed mode 504, and a mechanical trim mode 506, respectively utilized for three ranges of ambient conditions of temperature and humidity. Mechanical cooling mode 508 is (or can be) used for all three ranges of ambient conditions that include instances of outside contaminants 103.

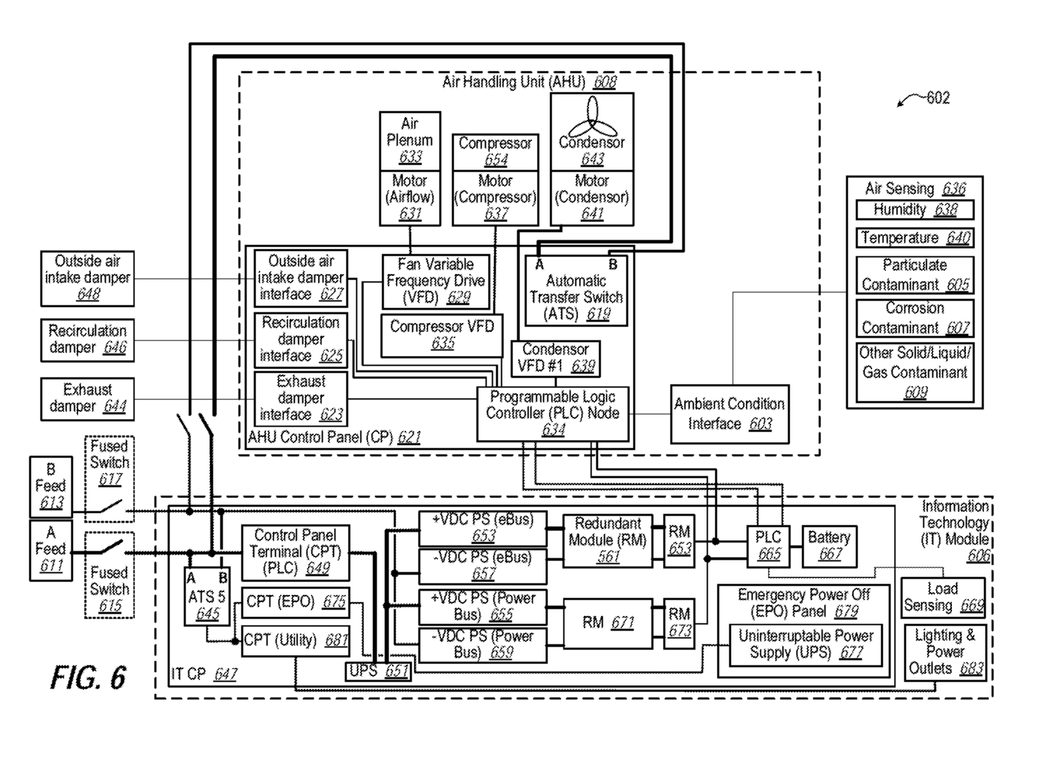

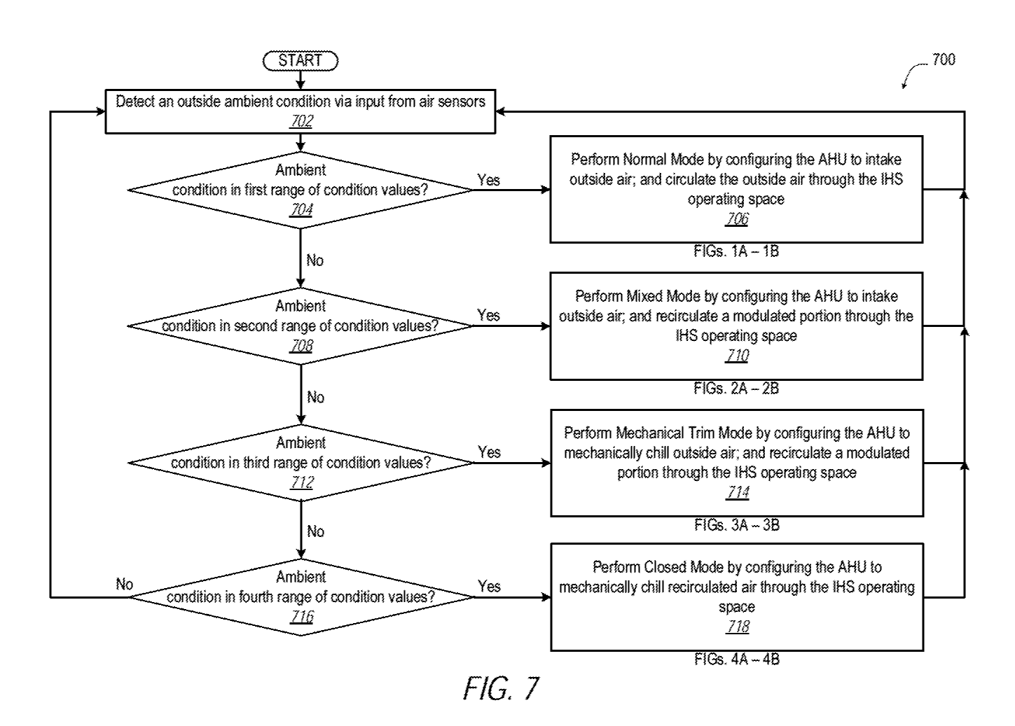

FIG. 6 illustrates an exemplary power and computing environment of an example mixed/multi-mode (MMC) cooling system 602 that configures an air handling unit (AHU) 608 to efficiently cool an IT module 606 of a data center 600. A programmable logic controller (PLC) node (“controller”) 634 of the MMC cooling system 602 communicates via an ambient condition interface 603 to outside air sensing components 636 to ascertain suitability of using outside air for cooling. For example, the outside air sensing components (or air sensors) 636 can include a relative humidity sensor 638 and a temperature sensor 640. As shown, the outside air sensing components 636 can also include a particulate contaminant sensor 605, a corrosion contaminant sensor 607, and other solid/liquid/gas contaminant sensor 609. Certain outside conditions, including, but not limited to temperature and humidity, can render the outside air unsuitable for direct use, and require the MMC System 602 to implement a different mode of cooling.

Turning now to the power aspects and communication aspects of MMC system 602, “A” feed source 611 and “B” feed source 613 provide electrical power for the MMC cooling system 602 via respective fused switches 615, 617. AHU 608 receives the “A” and “B” feeds at an automatic transfer switch (ATS) 619 in an AHU control panel (CP) 621. ATS 619 in turn provides power to the Controller 634 that activates other components in AHU 608. For example, the Controller 634 can communicate with an exhaust damper interface 623 to activate an exhaust damper 644. The Controller 634 can communicate with a recirculation damper interface 625 to activate a recirculation damper 646. The Controller 634 can communicate with an outside air intake damper interface 627 to activate an outside air intake damper 648. The Controller 634 can communicate with a fan variable frequency drive (VFD) 629 that activates an air flow motor 631 of an air plenum 633. The Controller 634 can communicate with a compressor VFD 635 that activates a compressor motor 637 of an air plenum 633. And, the Controller 634 can communicate with a condenser VFD #1 639 that activates a condenser motor 641 that turns a condenser fan 643.

IT module 606 also receives the “A” and “B” feeds at an ATS 645 in an IT CP 647. The “A” feed also passes through a PLC control panel terminal (CPT) 649 to an uninterruptable power supply (UPS) 651 that in turn passes “A” feed to eBus +VDC power supply (PS) 653 and to power bus +VDC PS 655. “B” feed is passed to eBus −VDC PS 657 and to power bus −VDC PS 659. The eBus+VDC PS 653 and eBUS −VDC PS 657 provide electrical power through two series redundant modules (RM) 661, 663 to an IT PLC 665 having a battery backup 667 as well as to the Controller 634 in the AHU 608 that monitors eBus status. The IT PLC 665 also communicates with Controller 634 to indicate data from load sensing components 669. Power bus +VDC PS 655 and power bus −VDC PS 659 provide electrical power through two series RMs 671, 673 to the IT PLC 665 and to the Controller 634. An output of the IT ATS 645 passes through an emergency power off (EPO) CPT 675 to a UPS 677 of an emergency panel off (EPO) panel 679. The output of the IT ATS 645 also passes through a utility CPT 681 to lighting and power outlets 683.

Increasing the use of outside air was shown by deterministic analysis to provide substantial power savings for several illustrative locations as detailed in the following table. TABLE 2 provides outside conditions for Santiago, Chile (10 year average values for each mode are used in power usage efficiency (PUE) calculation):

TABLE 2
% of Hours per Range

| | 2003 | 2004 | 2005 | 2006 | 2007 | 2008 | 2009 | 2010 | 2011 | 2012 |
|---|---|---|---|---|---|---|---|---|---|---|
| Mechanical | 2.2% | 1.5% | 2.2% | 1.8% | 1.4% | 2.1% | 3.2% | 2.4% | 2.8% | 3.1% |
| Cooling (MC) | | | | | | | | | | |
| Outside Air (Free | 9.0% | 9.4% | 7.6% | 8.6% | 7.2% | 10.0% | 8.8% | 8.2% | 8.0% | 9.0% |
| Air) | | | | | | | | | | |
| Hot Air Mixing | 88.8% | 89.4% | 90.2% | 89.7% | 91.3% | 88.1% | 88.0% | 89.4% | 89.2% | 88.2% |
| (Free Air) | | | | | | | | | | |
| Humidification | 10.5% | 6.9% | 4.5% | 4.2% | 17.3% | 5.4% | 10.1% | 11.8% | 15.2% | 10.7% |
| needed | | | | | | | | | | |

FIG. 7 illustrates a method 700 for cooling IT modules using one of four modes within a large scale IHS having an AHU. In one embodiment, the method 700 includes detecting an outside ambient condition as being in one of four ranges via input from air sensors 636 (block 702). The method 700 includes determining whether the outside ambient condition is within a first range of condition values (decision block 704). In response to determining in decision block 704 that the outside ambient condition falls within the first range of condition values, the method 700 includes performing Normal Mode as discussed above in regard to FIGS. 1A-1B by configuring the AHU to intake outside air, circulate the outside air through the IHS operating space, and exhaust the warmed air (block 706). Then, method 700 returns to block 702 to monitor the outside ambient condition.

In response to determining in decision block 704 that the outside ambient condition did not fall within the first range of condition values, the method 700 includes determining whether the outside ambient condition is within a second range of condition values (decision block 708). In response to determining in decision block 708 that the outside ambient condition is within the second range of condition values, the method 700 includes performing Mixed Mode as discussed above in regard to FIGS. 2A-2B by configuring the AHU to intake outside air, circulate the outside air through the IHS operating space along with a mix of recirculated, warmed air of a modulated amount (e.g., 5-95%), and exhaust the remainder of the warmed air (block 710). The range of recirculated air can be varied between 0-100% with the remainder being exhausted. In the illustrative embodiments of FIGS. 1-4, the position of the dampers are utilized to control the amount of the hot exhaust air that is actually exhausted to the outside versus the amount of the air that is recirculated, with the exhaust damper 144 ranging between a fully closed position (0% exhaust) to a fully open (100% exhausted) position, and the recirculation damper 146 concurrently being moved between a fully closed position and a full openend position. From block 710, method 700 returns to block 702 as the sensors continually monitor the outside ambient condition.

In response to determining in decision block 708 that the outside ambient condition did not fall within the second range of condition values, the method 700 includes determining whether the outside ambient condition is within a third range of condition values (decision block 712). In response to determining in decision block 712 that the outside ambient condition is within the third range of condition values, the method 700 includes performing Mechanical Trim Mode as discussed above in regard to FIGS. 3A-3B by configuring the AHU to intake outside air, circulate the outside air through the IHS operating space while mechanically chilling the air, and exhaust the warmed air (block 714). Then, method 700 returns to block 702 to monitor the outside ambient condition.

In response to determining in decision block 712 that the outside ambient condition did not fall within the third range of condition values, the method 700 includes determining whether the outside ambient condition is within a fourth range of condition values (decision block 716). In response to determining in decision block 716 that the outside ambient condition is within the fourth range of condition values, the method 700 includes performing Closed Mode as discussed above in regard to FIGS. 4A-4B by configuring the AHU to wholly recirculate air through the IHS operating space while mechanically chilling the air (block 718). Then, method 700 returns to block 702 to monitor the outside ambient condition. In response to determining in decision block 716 that the outside ambient condition did not fall within the fourth range of condition values, then method 700 returns to block 702 to monitor the outside ambient condition.

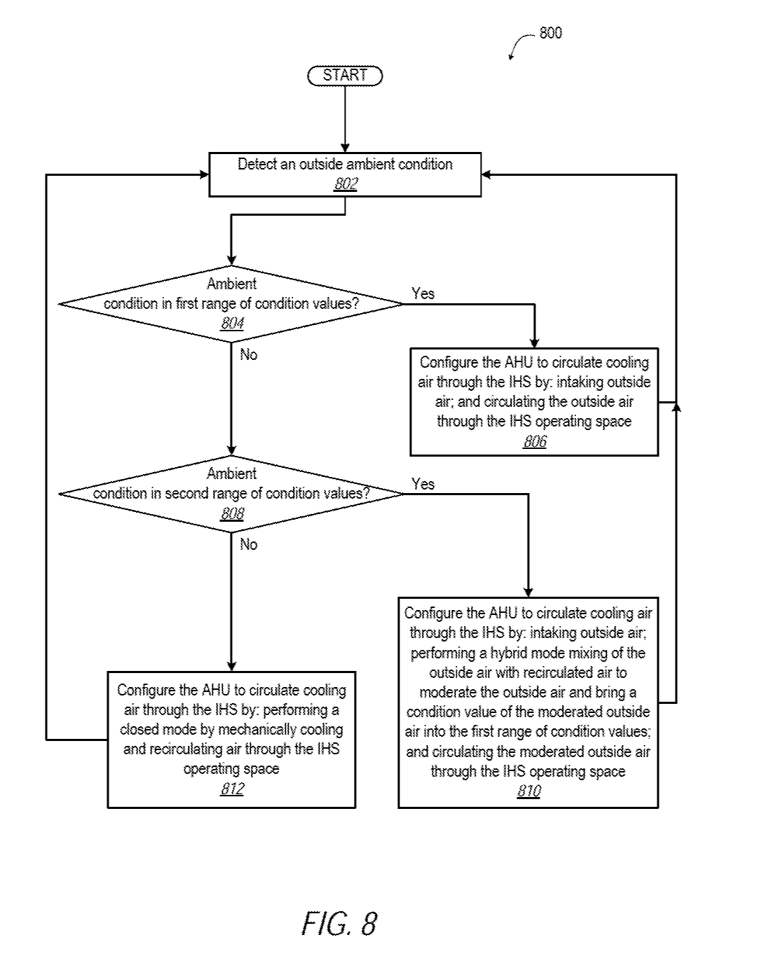

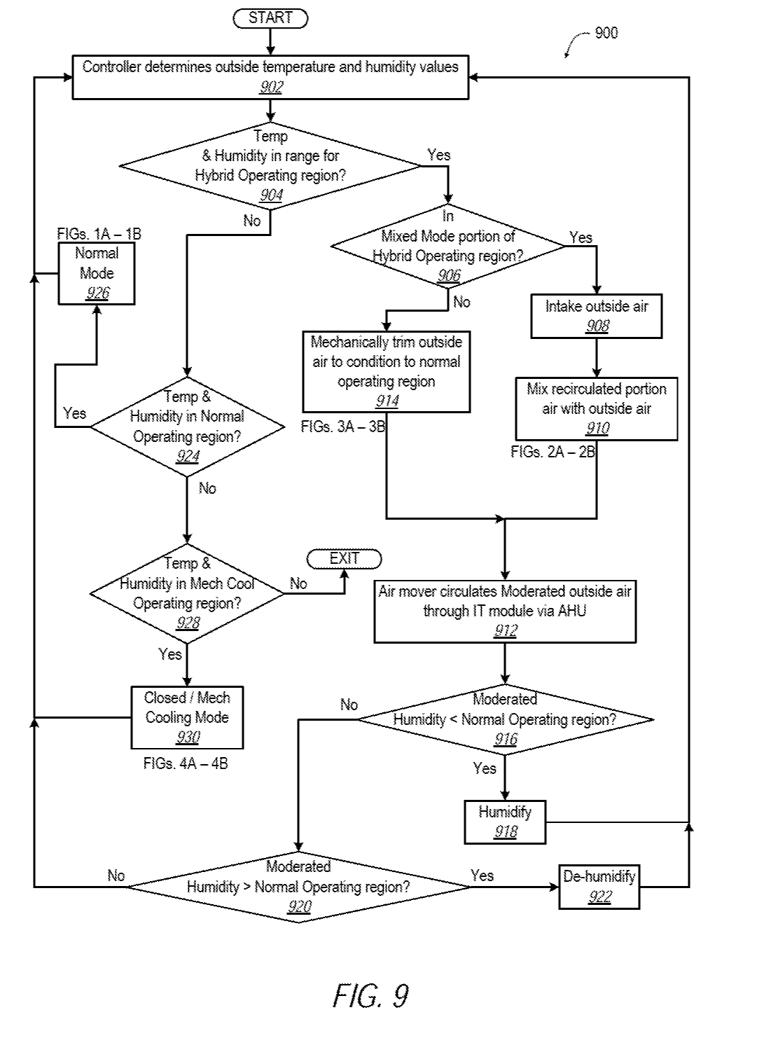

FIG. 8 illustrates a method 800 for cooling IT modules within a large scale IHS having an AHU. In one embodiment, the method 800 includes detecting an outside ambient condition (block 802). The method 800 includes determining whether the outside ambient condition is within a first range of condition values (decision block 804). In response to determining in decision block 804 that the outside ambient condition falls within the first range of condition values, the method 800 includes configuring the AHU to circulate cooling air through the IHS by: intaking outside air; and circulating the outside air through the IHS operating space (block 806). Then, method 800 returns to block 802 to monitor the outside ambient condition. In response to determining in decision block 804 that the outside ambient condition is not within the first range of condition values, then the method 800 includes determining whether the outside ambient condition is within a second range of condition values (decision block 808). In response to determining in decision block 808 that the outside ambient condition falls within the second range of condition values, the method 800 includes configuring the AHU to circulate cooling air through the IHS by: intaking outside air; performing a hybrid mode mixing of the outside air with recirculated air to moderate the outside air and bring a condition value of the moderated outside air into the first range of condition values; and circulating the moderated outside air through the IHS operating space (block 810). Then method 800 returns to block 802 to monitor the outside ambient condition. In response to determining in decision block 808 that the outside ambient condition falls outside the second range of condition values (i.e., the ambient condition falls within a third range of condition values that is neither the first range nor the second range), the method 800 includes configuring the AHU to circulate cooling air through the IHS by: performing a closed mode cooling by mechanically cooling and recirculating air through the IHS operating space (block 812). Then method 800 returns to block 802 to monitor the outside ambient condition.

In one or more embodiments, the ambient condition comprises at least one of an outside temperature and an outside humidity. When the ambient condition includes both the outside temperature and the outside humidity, the method 700 includes detecting the ambient condition by detecting an outside temperature value and an outside humidity value. The first range of condition values include a first range of temperature values and a first range of humidity values. The second range of condition values include a second range of temperature values and a second range of humidity values. The hybrid cooling mode accounts for both the temperature and the humidity of the outside air when moderating the outside air to bring a final temperature and a final humidity of the moderated outside air within the first range of temperature values and the first range of humidity values. In one or more embodiments, when the ambient condition includes only one of the outside temperature and the outside humidity being outside of a respective first range of values, the hybrid cooling mode accounts for only the one condition that falls outside of its respective first range of values.

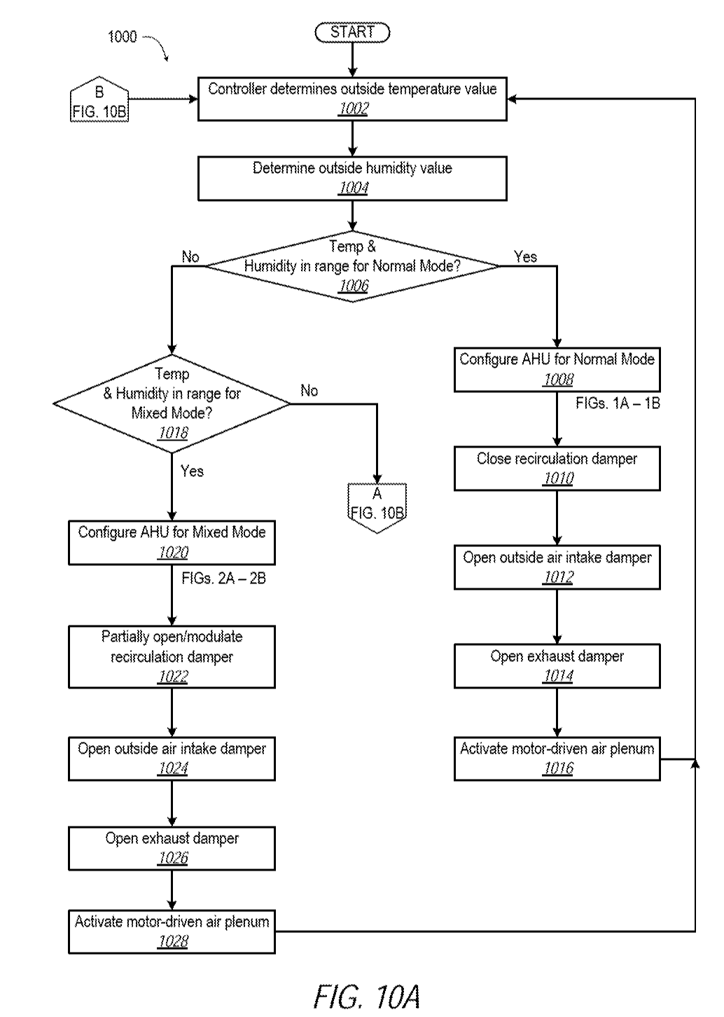

FIG. 9 illustrates a method 900 for cooling IT modules within a large scale IHS having an AHU. In one embodiment, the method 900 includes a controller determining an outside temperature value and an outside humidity value (block 902). The controller determines whether the outside temperature and humidity values are in respective ranges of a hybrid operating region that is outside of a two-dimensional range of a normal operating region. The normal operating region is a first range of condition values that requires normal cooling mode. The hybrid operating region is a second range of condition values that requires a hybrid cooling mode. In one embodiment, the first range of condition values include a first range of temperature values and a first range of humidity values. The second range of condition values include a second range of temperature values and a second range of humidity values. In one embodiment, in response to determining in decision block 904 that the outside temperature and humidity values are in the hybrid operating region, the controller makes a further determination as to whether the outside temperature and humidity values are more specifically in a portion of the hybrid space that is appropriate for mixed mode cooling in order to warm and dry the outside air (decision block 906). In response to determining in decision block 906 that the outside temperature and humidity values are in a portion of the hybrid space that is appropriate for mixed mode cooling in order to warm and dry the outside air, then the controller first configures the AHU to intake outside air (block 908). The controller also configures the AHU to perform a hybrid mode cooling in order to condition the outside air to have moderated temperature and humidity values in the normal operating region by mixing a portion of recirculated (warmed) air with the outside air (block 910). An air mover such as an air plenum blower circulates moderated outside air through the IHS via the AHU (block 912). For example, the air plenum blower can draw air from an air intake chamber of the AHU and expel the air into a confined space that directs air to a cold aisle of the IT module. Air then passes through rack-mounted IHSes in the IT module to a hot aisle that is in fluid communication with a hot air return plenum. Hot air returned in the hot air return plenum is partially sent through an exhaust portal and partially recirculated. In an exemplary embodiment, the controller configures the AHU by partially opening a recirculation damper between an air intake chamber and a hot air return plenum that are both in fluid communication with the IT module, opening an exhaust damper between the hot air return plenum and an exhaust portal, and closing an outside air intake damper at an outside air intake to the air intake chamber.

Returning to decision block 906, in response to determining in decision block 906 that the outside temperature and humidity values are in a portion of the hybrid space that is not appropriate for mixed mode cooling to warm and dry the outside air, the controller determines that the outside temperature and humidity values are in another portion of the hybrid space that is appropriate for mechanical trimming to condition the outside air to have a moderated air temperature that is within the normal operating region. In an exemplary embodiment, the controller configures the AHU by (i) partially opening a recirculation damper between an air intake chamber and a hot air return plenum that are both in fluid communication with the IT module, (ii) opening an exhaust damper between the hot air return plenum and an exhaust portal, and (iii) closing an outside air intake damper at an outside air intake to the air intake chamber (block 914). Then the air mover circulates moderated outside air through the IT module of the IHS via the AHU (block 912).

In one embodiment, the hybrid operating region can be defined based on the capacity of the mixing or the mechanical trimming operations to condition both the outside temperature and the outside humidity to be within the normal operating region. Alternatively in an exemplary embodiment, the hybrid operating region can be defined more broadly to encompass outside humidity values that can be brought into the normal operating region by either humidification or de-humidification apart from what occurs by mixing or mechanical trimming. FIG. 9 also includes a determination by the controller following completion of block 912 as to whether moderated humidity value of the moderated outside air is less than the normal operating region (decision block 916). In response to the determination in decision block 916 that the moderated humidity value of the moderated outside air is less than the normal operating region, then the controller causes a humidifier to humidify the moderated outside air (block 918). In response to the determination in decision block 916 that the moderated humidity value of the moderated outside air is not less than the normal operating region, then a further determination is made by controller as to whether the moderated humidity value of the moderated outside air is greater than the normal operating region (decision block 920). In response to the determination in decision block 920 that the moderated humidity value of the moderated outside air is greater than the normal operating region, then the controller causes a de-humidifier to de-humidify the moderated outside air (block 922). Method 900 then returns to block 902 to dynamically monitor outside temperature and outside humidity. Returning to decision block 920, in response to the determination in decision block 920 that the moderated humidity value of the moderated outside air is not greater than the normal operating region, then method 900 returns to block 902 to dynamically monitor outside temperature and outside humidity.

Returning to decision block 904, in response to determining that the outside temperature and humidity values are not in the hybrid operating region, the controller makes a further determination as to whether the outside temperature and humidity values are in the normal operating region (decision block 924). In response to the determination in decision block 924 that the outside temperature and humidity values are in the normal operating region, then the controller configures the AHU to perform normal operating mode by intaking outside air and expelling returned, warmed air without recirculation nor mechanical trimming (block 926). In an exemplary embodiment, the AHU is configured to perform a normal mode of outside air cooling by closing a recirculation damper between a hot air return plenum and an air intake chamber that are both in fluid communication with the IT module, opening an outside air intake damper at an outside air intake to the air intake chamber, opening an exhaust damper between the hot air return plenum and an exhaust portal, and moving the outside air through at least one IT module via the AHU. Method 900 then returns to block 902 to dynamically monitor outside temperature and outside humidity.

Returning to decision block 924, in response to determining that the outside temperature and humidity values are not in in the normal operating region, the controller makes a further determination as to whether the outside temperature and humidity values are in the mechanical cooling operating region (decision block 928). In response to the determination in decision block 929 that the outside temperature and humidity values are in the mechanical cooling operating region that requires closure of the system to outside air, then the controller configures the AHU to perform mechanical cooling operating mode by recirculating and mechanically cooling air within the IT module and AHU without intaking or exhausting. In an exemplary embodiment, the AHU is configured by perform a mechanical cooling mode by opening a recirculation damper between a hot air return plenum and an air intake chamber that are both in fluid communication with the IT module, closing an outside air intake damper at an outside air intake to the air intake chamber, closing an exhaust damper between the hot air return plenum and an exhaust portal, activating a direction expansion cooling unit, and moving the outside air through at least one IT module via the AHU (block 930). Method 900 then returns to block 902 to dynamically monitor outside temperature and outside humidity. In response to the determination in decision block 924 that the outside temperature and humidity values are not within the mechanical cooling operating region that is closed to outside air, then the method 900 ends.

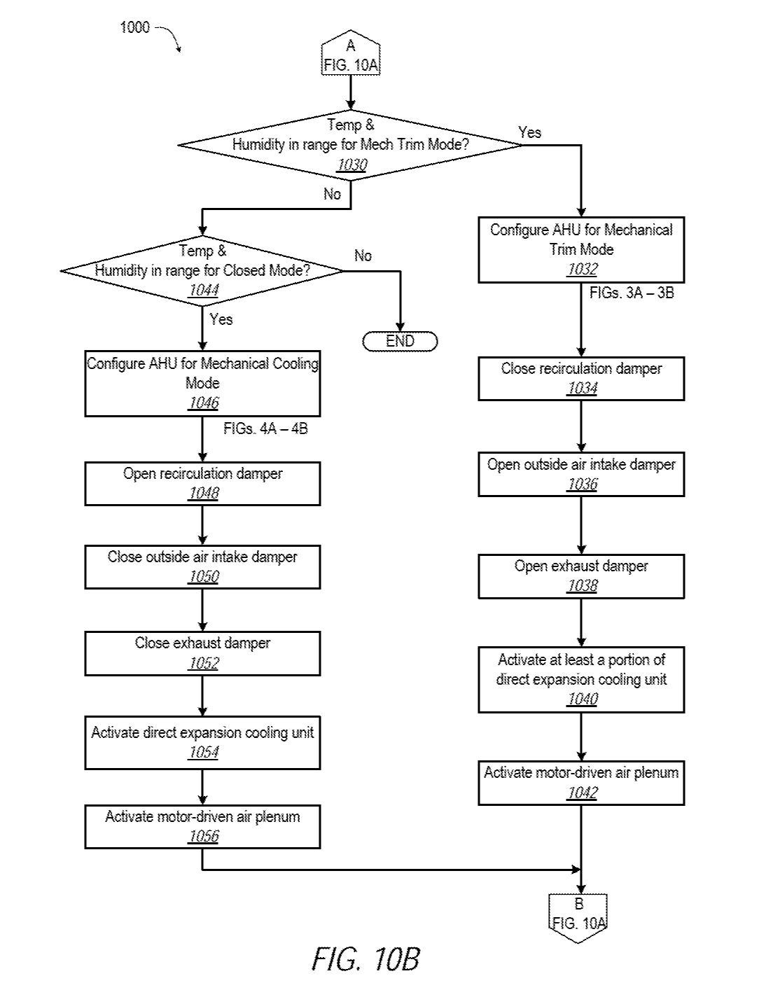

FIGS. 10A-10B illustrate an exemplary method 1000 of cooling a data center, with one of several modes, including a mixed mode operation, that are dynamically selected or implemented by a controller based on detected outside air temperatures and humidity, according to one or more embodiments. With initial reference to FIG. 10A, the method 1000 begins at start block. The method 1000 includes a controller determining an outside temperature value (block 1002). The controller also determines an outside humidity value (block 1004). The controller can then determine whether the outside temperature value is within an acceptable temperature range and whether and the outside humidity value is within an acceptable humidity range for cooling the IT modules of the IHSes via a normal mode involving use of the outside air (decision block 1006). In response to determining that both that the outside temperature value is within the acceptable temperature range and that the outside humidity value is within the acceptable humidity range, the controller configures an AHU to perform the normal mode of cooling using outside air to cool an IT module containing rack-mounted IHSes (block 1008). In particular, the controller closes a recirculation damper between a hot air return plenum and an air intake chamber (block 1010). The controller opens an outside air intake damper at an outside air intake to the air intake chamber (block 1012). The controller opens an exhaust damper between the hot air return plenum and an exhaust portal (block 1014). The controller activates a motor-driven air mover, such as an air plenum blower, to draw air through the IT module (block 1016). In particular, the air is drawn from the air intake chamber to a cold aisle of the IT module that in turn passes the air through the rack-mounted IHSes to a hot aisle of the IT module. The heated exhaust air is passed from the hot aisle to the hot air return plenum for expelling out of the exhaust portal. The method 1000 returns to block 1002 to dynamically monitor the outside conditions in order to select an appropriate mode should a change in the conditions occur that would trigger a different cooling mode of operation.

In response to determining in decision block 1006 that one of the outside temperature value and the outside humidity value is not in a range for normal mode cooling, the controller makes a further determination as to whether the outside temperature value is below the acceptable temperature range, while the outside humidity value is within the acceptable humidity range for cooling via mixed mode (decision block 1018). In response to the determination in decision block 1018 that at least one (or the combination of) the outside temperature value and outside humidity value are in the range pre-identified to trigger mixed mode cooling, controller configures the AHU to cool the IT module by implementing the mixed mode cooling (block 1020). In particular, the controller partially opens the recirculation damper between the hot air return plenum and the air intake chamber (block 1022). In one embodiment, the amount that the recirculation damper is opened is modulated in relation to the amount of heating of the outside air required to maintain an acceptable temperature range within the IT module. In one embodiment, a thermostat is utilized to track the temperature of the air inside the AHU. The thermostat is communicatively connected to the controller to provide real time temperature readings of the cooling air and moderated air. The controller opens the outside air intake damper at the outside air intake to the air intake chamber (block 1024). The controller opens the exhaust damper between the hot air return plenum and the exhaust chimney (block 1026). The controller activates the motor-driven air plenum blower to draw air through the IT module (block 1028). In particular, the air is drawn from the air intake chamber to the cold aisle of the IT module and the air in turn passes through the rack-mounted IHSes to the hot aisle of the IT module and ultimately to the hot air return plenum for partially exhausting out of the exhaust portal and partially recirculating. The method 1000 then returns to block 1002 to dynamically monitor outside conditions in order to select an appropriate mode.

In response to determining in decision block 1018 that at least one (or both of) the outside temperature value and the outside humidity value are not in a range for mixed mode cooling, method moves to FIG. 10B, which includes the controller determining whether at least one of the outside temperature value and the outside humidity value is within a range for mechanical trim mode cooling (decision block 1030). Mechanical trim mode relies on mechanical cooling in combination with outside air cooling. When in mechanical trim mode, the outside temperature value and outside humidity value are within a certain range that allows for a stepped down performance level of a direct expansion cooling unit in combination with outside air to be satisfactory. The outside humidity value is below a maximum humidity threshold such that cooling of the outside air will not result in moderated air that has a humidity level above what is acceptable for the IT module.

In response to the determination in decision block 1030 that the outside temperature value and the outside humidity value are within a range for implementing the mechanical trim mode, the controller configures the AHU for mechanical trim mode cooling and cools outside air with mechanically cooling (block 1032). In particular, the method 1000 includes the controller closing the recirculation damper between the hot air return plenum and the air intake chamber (block 1034). The controller opens the outside air intake damper at the outside air intake to the air intake chamber (block 1036). The controller opens the exhaust damper between the hot air return plenum and an exhaust portal (block 1038). The controller activates at least a portion of the direct expansion cooling unit that has an expansion unit with the air intake chamber (block 1040). The controller activates the motor-driven air plenum blower to draw air from the air intake chamber to the cold aisle of the IT module that in turn passes air through the rack-mounted IHSes to a hot aisle of the IT module and ultimately to the hot air return plenum for exhausting out of the exhaust portal (block 1042). The method 1000 then returns to block 1002 (FIG. 10A) to continue dynamically monitoring outside air conditions in order to select an appropriate cooling mode.

In response to determining in decision block 1030 that the outside temperature value and the outside humidity value are not in a range for mechanical trim mode, the method 1000 further includes the controller determining whether the outside temperature value and the outside humidity value are within a range for mechanical cooling mode (decision block 1044). In response to determining in decision block 1044 that the outside temperature value and the outside humidity value are within the range for mechanical cooling mode, the controller configures the AHU for mechanical cooling mode that precludes use of outside air (block 1032). In particular, the method 1000 includes the controller fully opening the recirculation damper between the hot air return plenum and the air intake chamber (block 1048). The controller closes the outside air intake damper at the outside air intake to the air intake chamber (block 1050). The controller closes the exhaust damper between the hot air return plenum and an exhaust chimney (block 1052). The controller activates the direct expansion cooling unit to cool the air drawn into the air intake chamber (block 1054). The controller activates the motor-driven air plenum blower to draw air from the hot air plenum into the air intake chamber (block 1056). The motor-driven air plenum blower pushes the moderated air into the cold aisle of the IT module. The air then passes air through the rack-mounted IHSes to the hot aisle of the IT module. The warmed air then returns to the hot air return plenum for full recirculation. The method 1000 then returns to block 1002 (FIG. 10A) to dynamically monitor outside conditions in order to select an appropriate mode. In response to determining in decision block 1042 that the outside temperature value and the outside humidity value are not in a range for mechanical cooling mode, the method 1000 ends. In one embodiment, the controller can perform error handling for encountering a temperature range for which there is not a defined cooling configuration of the AHU.

Embodiments according to the present disclosure can have more or less cooling modes than the four illustrative cooling modes of normal, mixed, mechanical trim and mechanical cooling. For example, a geographic location can have a climate pattern that makes one of the modes unnecessary or requires an additional mode.

The cooling system can be part of an Expandable Modular Information Technology (IT) Building Infrastructure (EMITBI) that supports a large-scale modularly-constructed information handling system (LMIHS). In one embodiment, a large compute pad/building structure has interior white space for racks and exterior walls that are designed to enable modular expansion of the structure by extending the build pad, constructing a second external wall, installing the additional IT gear in the extended white space, and then removing the previous exterior wall to create larger overall computer system without disrupting the IT gear, which remains operational during the expansion process; A scaled approach is provided to add devices and redundancy while physically expanding a data center (footprint) using pre-fabricated IT modules for cooling, power, and white space for future IT placement. An external wall can be added to a cold aisle module. Materials for modular walls can be lightweight composite fiber, metal panel with fiberglass insulation, structural foam panel, etc., with sound proofing considerations. The modular walls can provide mounting surfaces for sensors, etc. In one embodiment, the EMITBI includes dedicated hot and cold IT modules that are expandable. AHUs can sit on top of the structure for limited ground space applications or on one or two sides of the white space. AHUs can be added as needed when expansion occurs.

The cooling system can be part of configurable modular data center. Each of the modules may be dedicated to one of the primary elements of a data center, such as fluid handling, computing and power. Each of the plurality of modules may be separately configurable, according, at least in part, to operational and environmental requirements for the modular data center. The plurality of modules may then be incorporated into at least one modular data center structure, whose size and shape will depend, at least in part, on the configuration of each of the plurality of modules. One advantage is in escaping the design constraints of an existing containerized data center integrated into an International Organization for Standardization (ISO) shipping container. Breaking design elements into separately configurable modules generally removes the space limitations of an existing containerized data center.

In the above described flow charts of FIGS. 7-9 and 10A-10B, one or more of the methods may be embodied in an automated controller of a cooling system that performs a series of functional processes. In some implementations, certain steps of the methods are combined, performed simultaneously or in a different order, or perhaps omitted, without deviating from the scope of the disclosure. Thus, while the method blocks are described and illustrated in a particular sequence, use of a specific sequence of functional processes represented by the blocks is not meant to imply any limitations on the disclosure. Changes may be made with regards to the sequence of processes without departing from the scope of the present disclosure. Use of a particular sequence is therefore, not to be taken in a limiting sense, and the scope of the present disclosure is defined only by the appended claims.

One or more of the embodiments of the disclosure described can be implementable, at least in part, using a software-controlled programmable processing device, such as a microprocessor, digital signal processor or other processing device, data processing apparatus or system. Thus, it is appreciated that a computer program for configuring a programmable device, apparatus or system to implement the foregoing described methods is envisaged as an aspect of the present disclosure. The computer program may be embodied as source code or undergo compilation for implementation on a processing device, apparatus, or system. Suitably, the computer program is stored on a carrier device in machine or device readable form, for example in solid-state memory, magnetic memory such as disk or tape, optically or magneto-optically readable memory such as compact disk or digital versatile disk, flash memory, etc. The processing device, apparatus or system utilizes the program or a part thereof to configure the processing device, apparatus, or system for operation.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The description of the present disclosure has been presented for purposes of illustration and description, but is not intended to be exhaustive or limited to the disclosure in the form disclosed. Many modifications and variations will be apparent to those of ordinary skill in the art without departing from the scope of the disclosure. The described embodiments were chosen and described in order to best explain the principles of the disclosure and the practical application, and to enable others of ordinary skill in the art to understand the disclosure for various embodiments with various modifications as are suited to the particular use contemplated.

What is claimed is:

1. A cooling system that provides cooling air for an operating space of a large scale information handling system (IHS), the cooling system comprising:
an air handling unit (AHU) configured to direct cooling air through an information technology (IT) module within the IHS;
an ambient condition interface in communication with at least one outside ambient condition sensor that detects an ambient condition outside of the IHS; and
a controller in communication with the ambient condition interface and the AHU to cause the cooling system to:
detect the outside ambient condition;
determine whether the outside ambient condition is within a first range of condition values that requires normal cooling mode or within a second range of condition values that requires a hybrid cooling mode;
in response to determining that the outside ambient condition falls within the first range of condition values, configure the AHU to circulate cooling air through the IHS by:
intaking outside air; and
circulating the outside air through the IHS operating space; and
in response to determining that the outside ambient condition falls within the second range of condition values, configure the AHU to circulate cooling air through the IHS by:
intaking outside air;
performing a hybrid mode mixing of the outside air with recirculated air to moderate the outside air and bring a condition value of the moderated outside air into the first range of condition values; and
circulating the moderated outside air through the IHS operating space.

2. The cooling system of claim 1, wherein:
the ambient condition comprises at least one of an outside temperature and an outside humidity, and the ambient condition sensor comprises a respective outside sensor and an outside humidity sensor;
when the ambient condition includes both the outside temperature and the outside humidity:
detecting the ambient condition includes detecting an outside temperature value and an outside humidity value;
the first range of condition values include a first range of temperature values and a first range of humidity values;
the second range of condition values include a second range of temperature values and a second range of humidity values; and
the hybrid cooling mode accounts for both the temperature and the humidity of the outside air when moderating the outside air to bring a final temperature and a final humidity of the moderated outside air within the first range of temperature values and the first range of humidity values; and
when the ambient condition includes only one of the outside temperature and the outside humidity being outside of a respective first range of values, the hybrid cooling mode accounts for only the one condition that falls outside of its respective first range of values.

3. The cooling system of claim 1, wherein:
the controller further triggers the AHU to implement the hybrid cooling mode to moderate the outside air by mixing a recirculated portion of air that is warmed by the IHS with the outside air to warm and/or dry the outside air by:
partially opening a recirculation damper between an air intake chamber and a hot air return plenum that are both in fluid communication with the IT module;
opening an exhaust damper between the hot air return plenum and an exhaust portal; and
closing an outside air intake damper at an outside air intake to the air intake chamber.

4. The cooling system of claim 1, further comprising:
a humidifier that controllably increases humidity of air within the AHU;
a de-humidifier that controllably reduces humidity from within the air in the AHU;
wherein the controller further triggers the AHU to implement the hybrid cooling mode to moderate by:
triggering the AHU to change the outside temperature value of the outside air to a moderated temperature value that is in the first temperature range;
determining a moderated humidity value of the moderated outside air that results from changing the outside air to the moderated temperature value;
in response to the moderated humidity value being greater than the normal operating space, activating the de-humidifier to dehumidify the moderated outside air; and
in response to the moderated humidity value being less than the first range of humidity values, activating the humidifier to humidify the moderated outside air.

5. The cooling system of claim 1, further comprising: a direct expansion cooling unit that can be controlled to cool air within the AHU; wherein, in response to the detected outside ambient condition indicating that a humidity of the outside air is not within the first range of values, the controller further implements the hybrid cooling mode to moderate the outside air by activating at least a portion of the direct expansion cooling unit to mechanically trim the outside air.

6. The cooling system of claim 5, wherein the AHU further comprises:
a hot air return plenum in fluid communication with a hot aisle of the IT module and having an exhaust portal;
an air intake chamber in fluid communication with the hot air return plenum and having an air intake and air outlet;
an outlet chamber in fluid communication (i) with the air intake chamber via the air outlet and (ii) with a cold aisle of the IT module;
a recirculation damper between the hot air return plenum and the air intake chamber;
an outside air intake damper between the outside air intake and the air intake chamber;
an exhaust damper between the hot air return plenum and the exhaust portal; and
an air mover positioned to move air from the outlet chamber to the cold aisle of the IT module; and
wherein the controller further triggers the AHU to mechanically trim the outside air by closing the recirculation damper, opening the exhaust damper, opening the outside air intake damper, and activating the air mover.

7. The cooling system of claim 6, wherein the air mover comprises a motor-driven air plenum blower positioned to draw air from the air intake chamber to the cold aisle of the IT module that in turn passes air through rack-mounted IHSes to the hot aisle of the IT module and ultimately to the hot air return plenum.

8. The cooling system of claim 6, wherein the controller further:
determines whether outside temperature and humidity values are outside of both the first and second ranges of condition values; and
in response to the outside temperature and humidity values being outside of both the first and second ranges of condition values, configures the AHU to mechanically cool recirculated air through the IT module by opening the recirculation damper; closing the outside air intake damper; closing the exhaust damper; and activating the direct expansion cooling unit to cool air recirculated within the AHU.

9. The cooling system of claim 6, wherein the controller further, in response to determining that the outside temperature and humidity values are within the first range of condition values, configures the AHU to perform a normal mode of outside air cooling by: closing the recirculation damper; opening the outside air intake damper; opening the exhaust damper; and activating the air mover.

10. The cooling system of claim 6, further comprising: a chiller system having an insulated storage tank containing a liquid that is cooled by the direct expansion cooling unit and which exchanges heat in the AHU.

11. A method for cooling information technology (IT) modules within a large scale information handling system (IHS) having an air handling unit (AHU), the method comprising:
detecting an outside ambient condition;
determining whether the outside ambient condition is within a first range of condition values that requires normal cooling mode or within a second range of condition values that requires a hybrid cooling mode;
in response to determining that the outside ambient condition falls within the first range of condition values, configuring the AHU to circulate cooling air through the IHS by:
intaking outside air; and
circulating the outside air through the IHS operating space; and
in response to determining that the outside ambient condition falls within the second range of condition values, configuring the AHU to circulate cooling air through the IHS by:
intaking outside air;
performing a hybrid mode mixing of the outside air with recirculated air to moderate the outside air and bring a condition value of the moderated outside air into the first range of condition values; and
circulating the moderated outside air through the IHS operating space.

12. The method of claim 11, wherein:
the ambient condition comprises at least one of an outside temperature and an outside humidity;
when the ambient condition includes both the outside temperature and the outside humidity:
detecting the ambient condition includes detecting an outside temperature value and an outside humidity value;
the first range of condition values include a first range of temperature values and a first range of humidity values;
the second range of condition values include a second range of temperature values and a second range of humidity values; and
the hybrid cooling mode accounts for both the temperature and the humidity of the outside air when moderating the outside air to bring a final temperature and a final humidity of the moderated outside air within the first range of temperature values and the first range of humidity values; and
when the ambient condition includes only one of the outside temperature and the outside humidity being outside of a respective first range of values, the hybrid cooling mode accounts for only the one condition that falls outside of its respective first range of values.

13. The method of claim 11, wherein:
triggering the AHU to implement the hybrid cooling mode to moderate the outside air by mixing a recirculated portion of air that is warmed by the IHS with the outside air to warm and/or dry the outside air further comprises:
partially opening a recirculation damper between an air intake chamber and a hot air return plenum that are both in fluid communication with the IT module;
opening an exhaust damper between the hot air return plenum and an exhaust portal; and
closing an outside air intake damper at an outside air intake to the air intake chamber.

14. The method of claim 11, wherein:
triggering the AHU to implement the hybrid cooling mode to moderate further comprises:
triggering the AHU to change the outside temperature value of the outside air to a moderated temperature value that is in the first temperature range;
determining a moderated humidity value of the moderated outside air that results from changing the outside air to the moderated temperature value;
in response to the moderated humidity value being greater than the normal operating space, activating a de-humidifier to dehumidify the moderated outside air; and
in response to the moderated humidity value being less than the first range of humidity values, activating a humidifier to humidify the moderated outside air.

15. The method of claim 11, wherein, in response to the detected outside ambient condition indicating that a humidity of the outside air is not within the first range of values, implementing the hybrid cooling mode to moderate the outside air further comprises activating at least a portion of a direct expansion cooling unit to mechanically trim the outside air.

16. The method of claim 15, wherein the AHU further comprises:
a hot air return plenum in fluid communication with a hot aisle of the IT module and having an exhaust portal;
an air intake chamber in fluid communication with the hot air return plenum and having an air intake and air outlet;
an outlet chamber in fluid communication (i) with the air intake chamber via the air outlet and (ii) with a cold aisle of the IT module;
a recirculation damper between the hot air return plenum and the air intake chamber;
an outside air intake damper between the outside air intake and the air intake chamber;
an exhaust damper between the hot air return plenum and the exhaust portal; and
an air mover positioned to move air from the outlet chamber to the cold aisle of the IT module; and
wherein triggering the AHU to mechanically trim the outside air further comprises closing the recirculation damper, opening the exhaust damper, opening the outside air intake damper, and activating the air mover.

17. The method of claim 16, wherein the air mover comprises a motor-driven air plenum blower positioned to draw air from the air intake chamber to the cold aisle of the IT module that in turn passes air through rack-mounted IHSes to the hot aisle of the IT module and ultimately to the hot air return plenum.

18. The method of claim 16, further comprising:
determining whether outside temperature and humidity values are outside of both the first and second ranges of condition values; and
in response to the outside temperature and humidity values being outside of both the first and second ranges of condition values, configuring the AHU to mechanically cool recirculated air through the IT module by opening the recirculation damper; closing the outside air intake damper; closing the exhaust damper; and activating the direct expansion cooling unit to cool air recirculated within the AHU.

19. The method of claim 16, further comprising:
in response to determining that the outside temperature and humidity values are within the first range of condition values, configuring the AHU to perform a normal mode of outside air cooling by: closing the recirculation damper; opening the outside air intake damper; opening the exhaust damper; and activating the air mover.

20. The method of claim 16, wherein activating at least a portion of the direct expansion cooling unit to mechanically trim the outside air further comprises activating a chiller system having an insulated storage tank containing a liquid that is cooled by the direct expansion cooling unit and which exchanges heat in the AHU.
